(19) United States
(12) Patent Application Publication
(10) Pub. No.: US 2007/0267658 A1
(43) Pub. Date: Nov. 22, 2007

(54) Image sensor and methods of fabricating the same

(75) Inventors: Jae-Ho Song, Suwon-si (KR); Jong-Chae Kim, Yongin-si (KR); Jong-Wook Hong, Seoul (KR); Keo-Sung Park, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/798,391

(22) Filed: May 14, 2007

(30) Foreign Application Priority Data
May 17, 2006 (KR) 10-2006-0044325

(51) Int. Cl. H01L 27/10

(52) U.S. Cl. 257/211

(57) ABSTRACT

An image sensor and methods of fabricating the same are provided. An example method may include forming at least one gate on a substrate, forming first, second and third layers on the at least one gate, first etching the third layer with a first etching process, the second layer configured to be resistant to the first etching process, the first etching process reducing at least a portion of the third layer and exposing at least a portion of the second layer and second etching at least the exposed portion of the second layer with a second etching process other than the first etching process, the first layer configured to be resistant to the second etching process.

### PRIORITY STATEMENT

This U.S. non-provisional patent application claims priority under 35 U.S.C. §119 of Korean Patent Application No. 2006-44325, filed on May 17, 2006, the entire contents of which are hereby incorporated by reference.

### BACKGROUND OF THE INVENTION

1. Field of the Invention

Example embodiments are directed generally to an image sensor and methods of fabricating the same.

2. Description of Related Art

Image sensors may be semiconductor devices that convert an optical image into an electrical signal. A charge coupled device (CCD) image sensor may be an example of a conventional well-known image sensor. The CCD image sensor may consume a relatively high amount of power to obtain higher allowable charge transfer efficiency, and may further include an additional auxiliary circuit for adjusting an image signal or generation of the standard video output. Accordingly, it may be difficult to integrate the additional auxiliary circuit with the CCD image sensor. Due to this difficultly, Complementary Metal-Oxide Semiconductor (CMOS) image sensors may be deployed as an alternative to the CCD image sensor.

A conventional CMOS image sensor may have a simpler structure than the CCD image sensor. In addition, the CMOS image sensor may obtain a relatively high integration and a lower power consumption because the CMOS image sensor may be fabricated using a relatively advanced CMOS fabrication process. A pixel of the CMOS image sensor may include a photodiode (e.g., a photosensor) and one or more field-effect transistors (hereinafter also referred to as transistors) for transfer/output of a charge stored in the photodiode.

FIGS. 1 through 3 are sectional views illustrating a process of fabricating a conventional image sensor.

Referring to FIG. 1, a device isolation layer (not illustrated) may be formed on a semiconductor substrate 1. A gate oxide layer and a gate conductive layer may be sequentially formed on the semiconductor substrate 1. The gate conductive layer and the gate oxide layer may be sequentially patterned to form a gate oxide pattern 2 and a gate electrode 3 that are sequentially stacked on an active region.

Referring to FIG. 2, first dopant ions may be selectively implanted to form a photodiode region 4 in the semiconductor substrate 1 at a first side of the gate electrode 3, and second dopant ions may be selectively implanted to form a floating doped region 5 on a second side of the gate electrode 3. At this point, the photodiode region 4 and the floating doped region 5 may be doped with n-type dopants. Thereafter, an oxide layer 6 may be conformally formed on the entire top surface of the semiconductor substrate 1.

Referring to FIG. 3, a blanket anisotropic etching process may be performed on the oxide layer 6 to form a spacer 6a on both sidewalls of the gate electrode 3. Although not illustrated, third dopant ions may be selectively implanted to form a higher-concentration region in the floating doped region 5.

During the conventional image sensor fabrication process of FIGS. 1 through 3, the top surfaces of the photodiode region 4 and the floating doped region 5 may be damaged due to the blanket anisotropic etching process for forming the spacer 6a. Accordingly, surface defects, such as dangling bonds, may be generated at the photodiode region 4 and the floating doped region 5. The surface defects of the photodiode region 4 may generate noise during operation. For example, the surface defects may generate electron-hole pairs (EHPs). Accordingly, a dark current may increase (e.g., even without incident external light), leading to a potential malfunction of the image sensor. Moreover, the surface defects of the floating doped region 5 may also generate EHPs (e.g., even without incident external light). Accordingly, the dark current may further increase, leading to an increased probability of failure of the image sensor.

### SUMMARY OF THE INVENTION

An example embodiment of the present invention is directed to an image sensor, including a photodiode region disposed in a first pixel active region defined in a substrate, a floating doped region disposed in a second pixel active region defined in the substrate and connected to a given side of the first pixel active region, a pixel gate insulating layer and a transfer gate stacked on the second pixel active region between the photodiode region and the floating doped region, a barrier insulating layer covering the photodiode region, the transfer gate and the floating doped region, a buffer insulating layer interposed between the barrier insulating layer and the photodiode region and between the barrier insulating layer and the floating doped region and a transfer spacer disposed on at least one sidewall of the transfer gate with the barrier insulating layer interposed therebetween, the transfer spacer including an L-shaped lower transfer pattern and an upper transfer pattern disposed on the lower transfer pattern, the lower transfer pattern including an insulating material having an etch selectivity with respect to the barrier insulating layer, the upper transfer pattern including an insulating material having an etch selectivity with respect to the lower transfer pattern.

Another example embodiment of the present invention is directed to a method for fabricating an image sensor, including defining a first pixel active region and a second pixel active region in a substrate, stacking a pixel gate insulating layer and a transfer on the second pixel active region adjacent to the first pixel active region, forming a buffer insulating layer on the substrate, forming a photodiode region in the first pixel active region, forming a floating doped region in the second pixel active region adjacent to a given side of the transfer gate, forming, on a top surface of the substrate, a barrier insulating layer, a first spacer insulating layer having an etch selectivity with respect to the barrier insulating layer, and a second spacer insulating layer having an etch selectivity with respect to the first spacer insulating layer and etching the second spacer insulating layer and the first spacer insulating layer to form a transfer spacer on first and second sidewalls of the transfer gate.

Another example embodiment of the present invention is directed to a method for fabricating an image sensor, including forming at least one gate on a substrate, forming first, second and third layers on the at least one gate, first etching the third layer with a first etching process, the second layer configured to be resistant to the first etching process, the first etching process reducing at least a portion of the third layer and exposing at least a portion of the second layer and second etching at least the exposed portion of the second layer with a second etching process other than the first etching process, the first layer configured to be resistant to the second etching process.

Another example embodiment of the present invention is directed to an image sensor capable of reducing (e.g., minimizing) a noise, such as a dark current, and a method of fabricating the same.

Another example embodiment of the present invention provides directed to an image sensor capable of reducing (e.g., minimizing) the surface damages of a photodiode region and a floating doped region to thereby reduce (e.g., minimize) a noise and a method of fabricating the same.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIGS. 1 through 3 are sectional views illustrating a process of fabricating a conventional image sensor.

FIG. 4 is an equivalent circuit diagram of a pixel in a Complementary Metal-Oxide Semiconductor (CMOS) image sensor according to an example embodiment of the present invention.

FIG. 5 is a plan view of an image sensor according to another example embodiment of the present invention.

FIG. 6 is a sectional view taken along lines I-I′ and II-II′ of FIG. 5.

FIG. 7 is a sectional view taken along the lines I-I′ and II-II′ of FIG. 5 according to another example embodiment of the present invention.

FIGS. 8 through 16 are sectional views taken along the lines I-I′ and II-II′ of FIG. 5 to illustrate a process of fabricating an image sensor according to another example embodiment of the present invention.

FIG. 17 is a sectional view taken along the lines I-I′ and II-II′ of FIG. 5 to illustrate a process of fabricating an image sensor illustrated in FIG. 7 according to another example embodiment of the present invention.

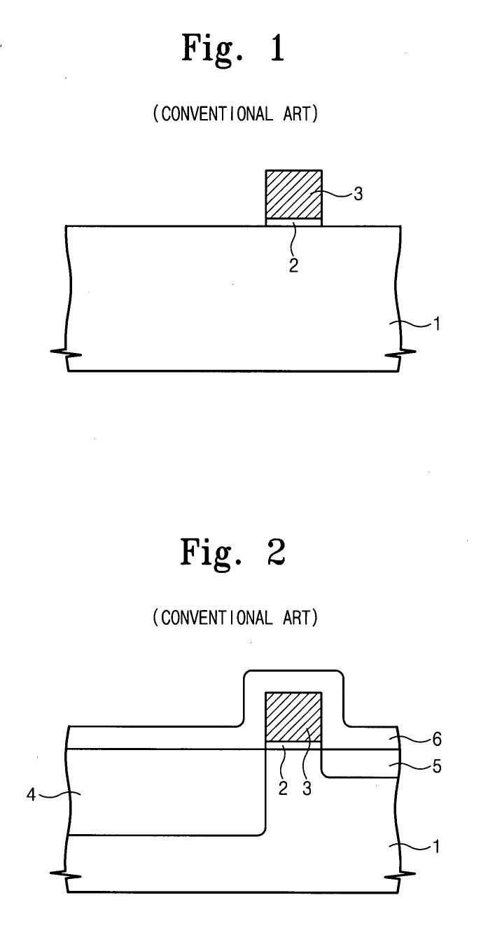

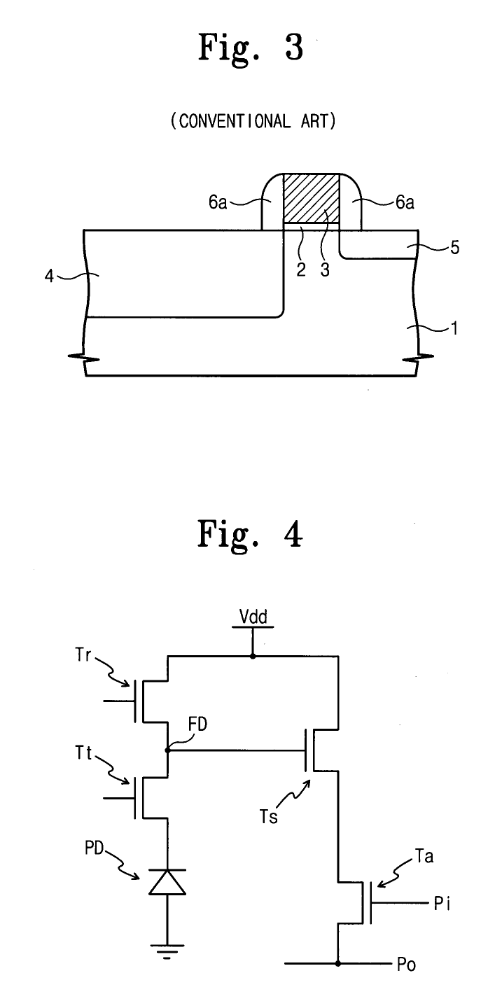

### DETAILED DESCRIPTION OF EXAMPLE EMBODIMENTS

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 4 is an equivalent circuit diagram of a pixel in a Complementary Metal-Oxide Semiconductor (CMOS) image sensor according to an example embodiment of the present invention.

In the example embodiment of FIG. 4, the pixel of the image sensor may include a photodiode PD. The photodiode PD may receive external light and may convert the received light into an electrical signal. The pixel may further include transistors Tt, Tr, Ts and Ta for controlling a charge stored in the photodiode PD. A first terminal of the photodiode PD may be connected to a source of the transfer transistor Tt, and a second terminal of the photodiode PD may be grounded. A drain of the transfer transistor Tt may be connected to a floating doped region FD.

In the example embodiment of FIG. 4, a gate of the sensing transistor Ts may be connected to the floating doped region FD, and a power voltage Vdd may be applied to a drain of the sensing transistor Ts. A source of the reset transistor Tr may be connected to the floating doped region FD, and the power source voltage Vdd may be applied to a drain of the reset transistor Tr. A source of the sensing transistor Ts may be connected to a drain of the access transistor Ta. A source of the access transistor Ta may be connected to an output port Po, and a gate of the access transistor Ta may be connected to an input port Pi. If a turn-on voltage is applied though the input port Pi, the access transistor Ta may be turned on and electrical data with information related to an image may be output through the output port Po. In an example, turn-on voltages applied to the input port Pi, the gate of the transfer transistor Tt and the gate of the reset transistor Tr may be substantially equal or similar to the power source voltage Vdd.

The example embodiment of FIG. 4 illustrates an example where the transistors of the pixel in the equivalent circuit diagram are NMOS transistors. In this example, the power source voltage Vdd may be a positive voltage. Alternatively, if the transistors are PMOS transistors, the voltages for operating the pixel may change accordingly. For example, if the transistors are PMOS transistors, the power source voltage Vdd may be a negative voltage.

Example operation of the pixel of FIG. 4 will now be described in greater detail. In example operation of the pixel of FIG. 4, if external light is incident upon the photodiode PD, charges may accumulate in the photodiode PD. The transfer transistor Tt may be turned on to move the accumulated charges of the photodiode PD into the floating doped region FD. Accordingly, a voltage of the floating doped region FD may change and a voltage of the gate of the sensing transistor Ts may be connected to the floating doped region FD changes. Consequently, an electrical signal output from the pixel may be adjusted according to the strength and/or intensity of the incident external light.

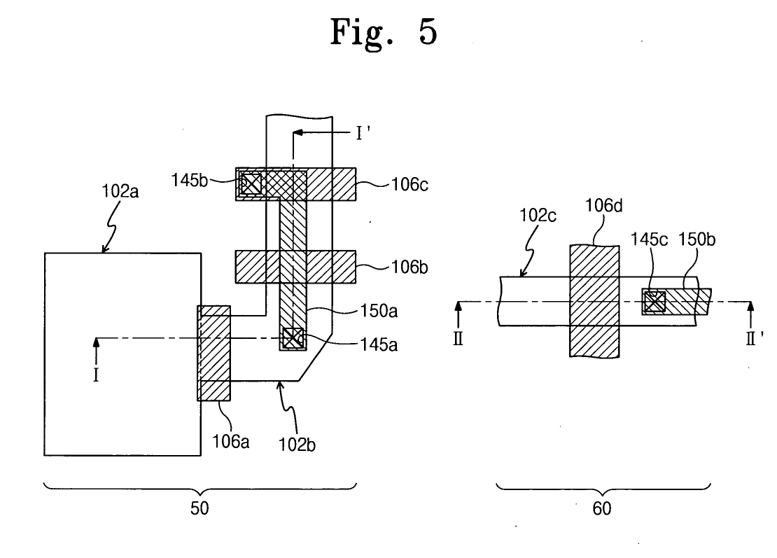

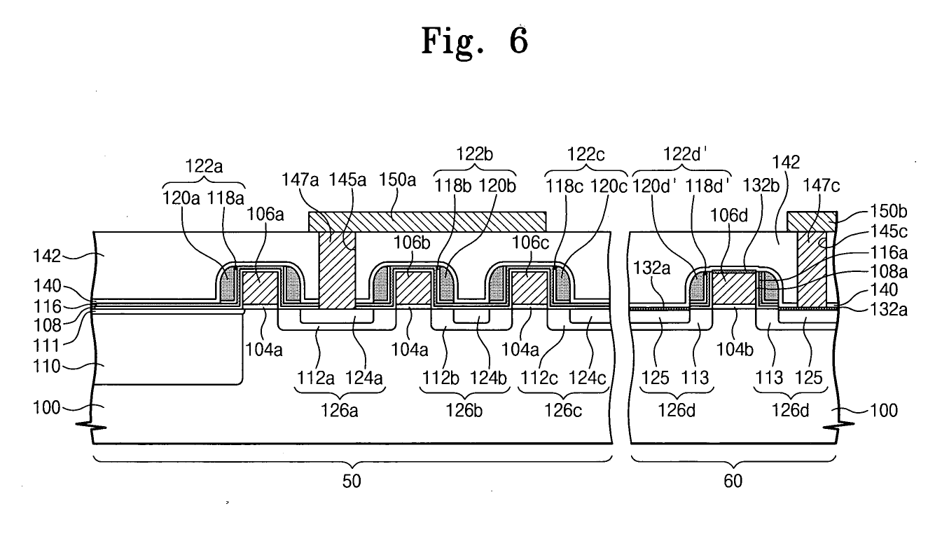

FIG. 5 is a plan view of an image sensor according to another example embodiment of the present invention. FIG. 6 is a sectional view taken along lines I-I′ and II-II′ of FIG. 5. In FIGS. 5 and 6, reference numerals 50 and 60 may denote a pixel region and a peripheral circuit region, respectively.

In the example embodiments of FIGS. 4 through 6, a device isolation layer may be disposed in a semiconductor substrate 100 (hereinafter simply referred to as a “semiconductor”). The device isolation layer may define first and second pixel active regions 102a and 102b in the pixel region 50 and a peripheral active region 102c in the peripheral circuit region 60. The second pixel active region 102b may be connected to a given side of the first pixel active region 102a. In an example, the device isolation layer may be a trench-type device isolation layer.

In the example embodiment of FIGS. 4 through 6, a photodiode region 110 may be disposed in the first pixel active region 102a. The photodiode region 110 may be doped with n-type dopants. The photodiode region 100 may form a PN junction with the substrate 100. The doping concentration of the photodiode region 110 may be lower such that at least a portion (e.g., a majority) of the photodiode region 110 may be a depletion region. A pinned doped region 111 may be disposed at a top portion of the photodiode region 110. The pinned doped region 111 may be doped with dopants whose type is different from that of the dopants of the photodiode region 110. For example, the pinned doped region 111 may be doped with p-type dopants. The pinned doped region 111 may function to discharge a dark current that may be generated at a top surface of the first pixel active region 102a.

In the example embodiments of FIGS. 4 through 6, a floating doped region 126a may be disposed in the second pixel active region 102b. The floating doped region 126a may be spaced apart from the photodiode region 110. In an example, the floating doped region 126a may be doped with dopants whose type is the same as that of the dopants of the photodiode region 110. For example, the floating doped region 126a may be doped with n-type dopants. The floating doped region 126a may include a floating lower-concentration region 112a and a floating higher-concentration region 124a. In an example, the floating doped region 126a may have a double-doped drain (DDD) structure in which the floating higher-concentration region 124a may be surrounded by the floating lower-concentration region 112a. Alternatively, the floating doped region 126a may have a lightly-doped drain (LDD) structure.

In the example embodiments of FIGS. 4 through 6, a transfer gate 106a may be disposed on the second pixel active region 102b between the photodiode region 110 and the floating doped region 126a. The transfer gate 106a may cover a portion of the first pixel active region 102a adjacent to the second pixel active region 102b. The transfer gate 106a, the photodiode region 110, and the floating doped region 126a may collectively constitute the transfer transistor Tt. The photodiode region 110 may constitute the photodiode PD and may also correspond to the source of the transfer transistor Tt. The floating doped region 126a may correspond to the drain of the transfer transistor Tt.

In the example embodiments of FIGS. 4 through 6, a reset gate 106b and a sensing gate 106c may be disposed on the second pixel active region 102b such that the reset gate 106b and the sensing gate 106c may be laterally spaced apart from each other. The reset gate 106b and the sensing gate 106c may be disposed at a given side of the transfer gate 106a such that the reset gate 106b and the sensing gate 106c may each be spaced apart from the transfer gate 106a. A first dopant-doped region 126b and a second dopant-doped region 126c may be disposed in the second pixel active region 102b at both first and second of the sensing gate 106c. The first dopant-doped region 126b may include a first lower-concentration region 112b and a first higher-concentration region 124b. Likewise, the second dopant-doped region 126c may include a second lower-concentration region 112c and a second higher-concentration region 124c. Like the floating doped region 126a, the first and second dopant-doped regions 126b and 126c may have a DDD structure or an LDD structure.

In the example embodiments of FIGS. 4 through 6, the floating doped region 126a may be disposed at the second pixel active region 102b between the transfer gate 106a and the reset gate 106b. The first dopant-doped region 126b may be disposed at the second pixel active region 102b between the reset gate 106b and the sensing gate 106c. The floating doped region 126a may be the drain of the transfer transistor Tt and may also correspond to the source of the reset transistor Tr. The reset gate 106b may correspond to the gate of the reset transistor Tr. The first dopant-doped region 126b may be the drain of the reset transistor Tr and may also correspond to the drain of the sensing transistor Ts. For example, the power source voltage Vdd may be applied to the first dopant-doped region 126b. The sensing gate 106c and the second dopant-doped region 126c may correspond respectively to the gate and source of the sensing transistor Ts. The second dopant-doped region 126c may be the drain of the access transistor Ta. The gate and source of the access transistor Ta have been illustrated in FIGS. 5 and 6 for the sake of simplicity.

In the example embodiments of FIGS. 4 through 6, a pixel gate insulating layer 104a may be interposed between the transfer gate 106a and the second pixel active region 102b, between the reset gate 106b and the second pixel active region 102b, and between the sensing gate 106c and the second pixel active region 102b.

In the example embodiments of FIGS. 4 through 6, a peripheral gate 106d may be disposed at an upper portion of the peripheral active region 102c. A peripheral gate insulating layer 104b may be interposed between the peripheral gate 106d and the peripheral active region 102c. Peripheral dopant-doped regions 126d may be disposed in the peripheral active region 102c at first and second sides of the peripheral gate 106d. The peripheral dopant-doped regions 126d may include a peripheral lower-concentration region 113 and a peripheral higher-concentration region 125. In an example, the peripheral dopant-doped region 126d may have a DDD structure or an LDD structure.

In the example embodiments of FIGS. 4 through 6, a barrier insulating layer 116 may cover (e.g., continuously cover) the photodiode region 110, the transfer gate 106a, and the floating doped region 126a. For example, the barrier insulating layer 116 may cover a top surface (e.g., an entirety of the top surface) of the photodiode region 110, the top and side surfaces of the transfer gate 106a, and a top surface (e.g., an entirety of the top surface) of the floating doped region 126a. The barrier insulating layer 116 may conformally cover the photodiode region 110, the transfer gate 106a, and the floating doped region 126a. As used herein, the term “conformally” may mean that a layer is formed in a substantially uniform thickness on the surface of a structure therebeneath (e.g., directly therebeneath, having one or more intervening layers to the intended structure, etc.).

In the example embodiments of FIGS. 4 through 6, a buffer insulating layer 108 may be interposed between the barrier insulating layer 116 and a top surface of the first pixel active region 102a in which the photodiode region 110 is disposed, between the barrier insulating layer 116 and the floating doped region 126a, and between the barrier insulating layer 116 and the transfer gate 106a.

In the example embodiments of FIGS. 4 through 6, the barrier insulating layer 116 may extend laterally to further cover the reset gate 106b, the first dopant-doped region 126b, the sensing gate 106c, and the second dopant-doped region 126c continuously. In another example, the barrier insulating layer 116 may cover (e.g., an entirety of) the pixel region 50 conformally. In this example, the buffer insulating layer 108 may also be disposed between the barrier insulating layer 116 and the first dopant-doped region 126b, between the barrier insulating layer 116 and the second dopant-doped region 126c, between the barrier insulating layer 116 and the reset gate 106b, and between the barrier insulating layer 116 and the sensing gate 106c.

In the example embodiments of FIGS. 4 through 6, the barrier insulating layer 116 may be formed of a relatively-dense insulating material. For example, the barrier insulating layer 116 may be formed of an insulating material capable of reducing (e.g., minimizing) the diffusion of metal elements. In an example, the barrier insulating layer 116 may be formed of an insulating material that has a lower metal diffusion coefficient than an oxide layer. In addition, the barrier insulating layer 116 may be formed of an insulating material with a good anti-reactivity. That is, the barrier insulating layer 116 may be formed of an insulating material that has a very low reactivity with respect to other materials. For example, the barrier insulating layer 116 may be formed of a nitride layer. The buffer insulating layer 108 may be formed of an insulating material capable of buffering a stress of the barrier insulating layer 116. For example, the buffer insulating layer 108 may be formed of a thermal oxide layer for enhancing the interfacial properties with respect to the first and second pixel active regions 102a and 102b. In another example, the gates 106a, 106b, 106c and 106d may be formed of a doped polysilicon.

In the example embodiments of FIGS. 4 through 6, a transfer spacer 122a may be disposed on both sidewalls of the transfer gate 106a. The transfer spacer 122 may be disposed on the barrier insulating layer 116. The barrier insulating layer 116 may be interposed between the transfer spacer 122a and the transfer gate 106a, between the transfer spacer 122a and the photodiode region 110, and between the transfer spacer 122a and the floating doped region 126a. The transfer spacer 122a may include an L-shaped lower transfer pattern 118a and an upper transfer pattern 120a disposed on the lower transfer pattern 118a. The lower transfer pattern 118a may be formed of an insulating material having an etch selectivity with respect to the barrier insulating layer 116, and the upper transfer pattern 120a may be formed of an insulating material having an etch selectivity with respect to the lower transfer pattern 118a. In an example, the upper transfer pattern 120a may be in the shape of a typical gate spacer.

In the example embodiments of FIGS. 4 through 6, a reset spacer 122b may be disposed on first and second sidewalls of the reset gate 106b. The barrier insulating layer 116 may be interposed between the reset gate 106b and the reset spacer 122b and between the reset spacer 122b and the second pixel active region 102b. A sensing spacer 122c may be disposed on first and second sidewalls of the sensing gate 106c. The barrier insulating layer 116 may be interposed between the sensing gate 106c and the sensing spacer 122c and between the sensing spacer 122c and the second pixel active region 102b. The reset spacer 122b may include an L-shaped lower reset pattern 118b and an upper reset pattern 120b disposed on the lower reset pattern 118b. In an example, the upper reset pattern 120b may be in the shape of a typical gate spacer. The sensing spacer 122c may include an L-shaped lower sensing pattern 118c and an upper sensing pattern 120c disposed on the lower sensing pattern 118c. In an example, the upper sensing pattern 120c may be in the shape of a typical gate spacer. In another example, the lower reset/sensing patterns 118b and 118c may be formed of the same material as the lower transfer pattern 118a. The upper reset/sensing patterns 120b and 120c may be formed of the same material as the upper transfer pattern 120a.

In the example embodiments of FIGS. 4 through 6, a peripheral spacer 122d′ may be disposed on first and second sidewalls of the peripheral gate 106d. The peripheral spacer 122d′ may include an L-shaped lower peripheral pattern 118d′ and an upper peripheral pattern 120d′ disposed on the lower peripheral pattern 118d′. A peripheral barrier pattern 116a may be interposed between the peripheral spacer 122d′ and the peripheral gate 106d and between the peripheral spacer 122d′ and the peripheral active region 102c. A peripheral buffer pattern 108a may be interposed between the peripheral barrier pattern 116a and the peripheral gate 106d and between the peripheral barrier pattern 116a and the peripheral active region 102c. In an example, the lower peripheral pattern 118d′ may be formed of the same material as the lower transfer pattern 118a, and the upper peripheral pattern 120d′ may be formed of the same material as the upper transfer pattern 120a. In another example, the peripheral barrier pattern 116a may be formed of the same material as the barrier insulating layer 116, and the peripheral buffer pattern 108a may be formed of the same material as the buffer insulating layer 108.

In the example embodiments of FIGS. 4 through 6, the top of the peripheral spacer 122d′ may be lower in height than the top of the transfer spacer 122a. The tops of the reset/sensing spacers 122b and 122c may be equal in height to the top of the transfer spacer 122a.

In the example embodiments of FIGS. 4 through 6, a first peripheral metal silicide 132a may be disposed on the peripheral dopant-doped region 126d at a given side of the peripheral spacer 122d′, and a second peripheral metal silicide 132b may be disposed on a top surface of the peripheral gate 106d. The first and second peripheral metal silicides 132a and 132b may include the same metal. For example, the first and second peripheral metal silicides 132a and 132b may be formed of one of cobalt silicide, nickel silicide, and titanium silicide.

In the example embodiments of FIGS. 4 through 6, a first dielectric layer 140 may conformally cover a top surface (e.g., an entirety of the top surface) of the substrate 100, and a second dielectric layer 142 may be disposed on the first dielectric layer 140. The second dielectric layer 142 may have a planarized top surface. The first dielectric layer 140 may have an etch selectivity with respect to the second dielectric layer 142. For example, the second dielectric layer 142 may include an oxide layer and the first dielectric layer 140 may include a nitride layer and/or a nitride oxide layer.

In the example embodiments of FIGS. 4 through 6, a first contact plug 147a may at least partially fill a first contact hole 145a, which may sequentially penetrate the second dielectric layer 142 and the first dielectric layer 140, and may be connected to the floating doped region 126a. A second contact hole 145b may sequentially penetrate the second dielectric layer 142, the first dielectric layer 140, the barrier insulating layer 116 and the buffer insulating layer 108 to expose the sensing gate 106c. A second contact plug (not illustrated) may at least partially fill the second contact hole 145b and may be connected to the sensing gate 106c. A third contact plug 147c may at least partially fill a third contact hole 145c, which may sequentially penetrate the second dielectric layer 142 and the first dielectric layer 140, and may be connected to the peripheral dopant-doped region 126d. In an example, the first, second and third contact plugs may include a conductive material.

In the example embodiments of FIGS. 4 through 6, a local interconnection 150a may be disposed on the second dielectric layer 142 of the pixel region 50. First and second ends of the local interconnection 150a may be connected respectively to the first contact plug 147a and the second contact plug. The sensing gate 106d and the floating doped region 60 may be connected to each other by the local interconnection 150a, and may be floated together. A peripheral interconnection 150b may be disposed on the second dielectric layer 142 of the peripheral circuit region 60. The peripheral interconnection 150b may be connected to the third contact plug 147c.

In the example embodiments of FIGS. 4 through 6, the photodiode region 110 and the floating doped region 126a may be at least partially covered by the barrier insulating layer 116. Accordingly, the photodiode region 110 and the floating doped region 126a may be at least partially protected from etch damage. In addition, the infiltration of metal elements into the photodiode region 110 and the floating doped region 126a may be reduced (e.g., minimized) by the barrier insulating layer 116. Consequently, an amount of dark current may be reduced and the characteristics of the image sensor may thereby be improved.

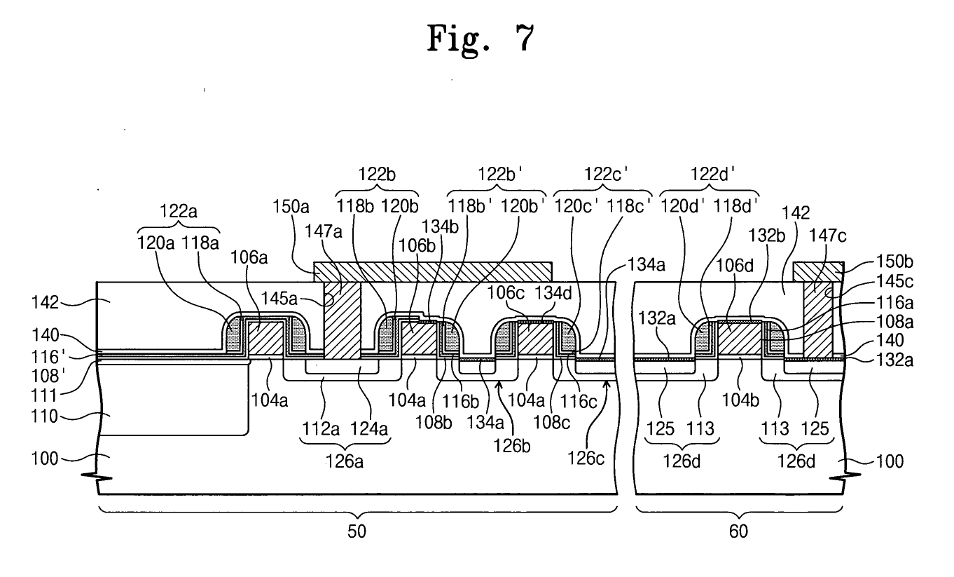

FIG. 7 is a sectional view taken along the lines I-I′ and II-II′ of FIG. 5 according to another example embodiment of the present invention.

In the example embodiments of FIGS. 5 and 7, a barrier insulating layer 116′ may at least partially cover a photodiode region 110, a transfer gate 106a, and a floating doped region 126a continuously and conformally. In addition, the barrier insulating layer 116′ may laterally extend to conformally cover a given sidewall of a reset gate 106b adjacent to the floating doped region 126a and a portion of a top surface of the reset gate 106b. A buffer insulating layer 108′ may be interposed between the barrier insulating layer 116′ and the photodiode region 110 and between the barrier insulating layer 116′ and the floating doped region 126a. In addition, the buffer insulating layer 108′ may be interposed between the barrier insulating layer 116′ and the transfer gate 106a and between the barrier insulating layer 116′ and the reset gate 106b.

In the example embodiments of FIGS. 5 and 7, a first reset spacer 122b may be disposed on a first sidewall of the reset gate 106b adjacent to the floating doped region 1126a, and a second reset spacer 122b′ may be disposed on a second sidewall of the reset gate 106b adjacent to the first dopant-doped region 126b. The first reset spacer 122b may include a first L-shaped lower reset pattern 118b and a first upper reset pattern 120b disposed on the first lower reset pattern 118b. The second reset spacer 122b′ may include a second L-shaped lower reset pattern 118b′ and a second upper reset pattern 120b′ disposed on the second lower reset pattern 118b′. In an example, the first and second lower reset patterns 118b and 118b′ may be formed of the same material as the lower transfer pattern 118a, and the first and second upper reset patterns 120b and 120b′ may be formed of the same material as the upper transfer pattern 120a.

In the example embodiments of FIGS. 5 and 7, the first reset spacer 122b may be disposed on the barrier insulating layer 116′, and the barrier insulating layer 116′ may be interposed between the first reset spacer 122b and the reset gate 106b. A reset barrier pattern 116b may be interposed between the reset gate 106b and the second reset spacer 122b′ and between the second reset spacer 122b′ and the second pixel active region 102b. A reset buffer pattern 108b may be interposed between the reset barrier pattern 116b and the reset gate 106b and between the reset barrier pattern 116b and the second pixel active region 102b. In an example, the reset barrier pattern 116b may be formed of the same material as the barrier insulating layer 116′, and the reset buffer pattern 108b may be formed of the same material as the buffer insulating layer 108′. In another example, the barrier insulating layer 116′ may be formed of the same material as the barrier insulating layer 116 (e.g., see FIG. 6), and the buffer insulating layer 108′ may be formed of the same material as the buffer insulating layer 108 (e.g., see FIG. 6). The top of the second reset spacer 122b′ may be lower in height than the top of the first reset spacer 122b.

In the example embodiments of FIGS. 5 and 7, a sensing spacer 122c′ may be disposed on first and second sidewalls of a sensing gate 106c. The sensing spacer 122c′ may include an L-shaped lower sensing pattern 118c′ and an upper sensing pattern 120c′ disposed on the lower sensing pattern 118c′. A sensing barrier pattern 116c may be interposed between the sensing gate 106c and the sensing spacer 122c′ and between the sensing spacer 122c′ and the second pixel active region 102b. A sensing buffer pattern 108c may be interposed between the sensing barrier pattern 116c and the sensing gate 106c and between the sensing barrier pattern 116c and the second pixel active region 102b. In an example, the lower sensing pattern 118c′ and the upper sensing pattern 120c′ may be formed of the same. material. In another example, the sensing barrier pattern 116c may be formed of the same material as the barrier insulating layer 116′, and the sensing buffer pattern 108c may be formed of the same material as the buffer insulating layer 108′. The top of the sensing spacer 122c′ may be lower in height than the top of the transfer spacer 122a. The top of the sensing spacer 122c′ may be equal in height to the top of the second reset spacer 122b′. The tops of the sensing spacer 122c′ and the second reset spacer 122b′ may be equal in height to the top of the peripheral spacer 122d′.

In the example embodiments of FIGS. 5 and 7, a first pixel metal silicide 134a may be disposed on a surface of the first dopant-doped region 126b between the second reset spacer 122b′ and on a surface of the second dopant-doped region 126c at a given side of the sensing spacer 122c′. A second pixel metal silicide 134b may be disposed on a top surface of the sensing gate 106c and on a portion of a top surface of the reset gate 106b. In an example, the first and second pixel metal silicides 134a and 134b may include the same material. In another example, the first pixel metal silicide 134a may be formed of the same material as the first peripheral metal silicide 132a, and the second pixel metal silicide 134b may be formed of the same material as the second peripheral metal silicide 132b.

In an alternative example embodiment, referring to FIGS. 5 and 7, a second contact hole 145b may sequentially penetrate a second dielectric layer 142 and a first dielectric layer 140 to expose the second pixel metal silicide 134b on the sensing gate 106c. Accordingly, a second contact plug (not illustrated) may at least partially fill the second contact hole 145b and may be connected through the second pixel metal silicide 134b to the sensing gate 106c.

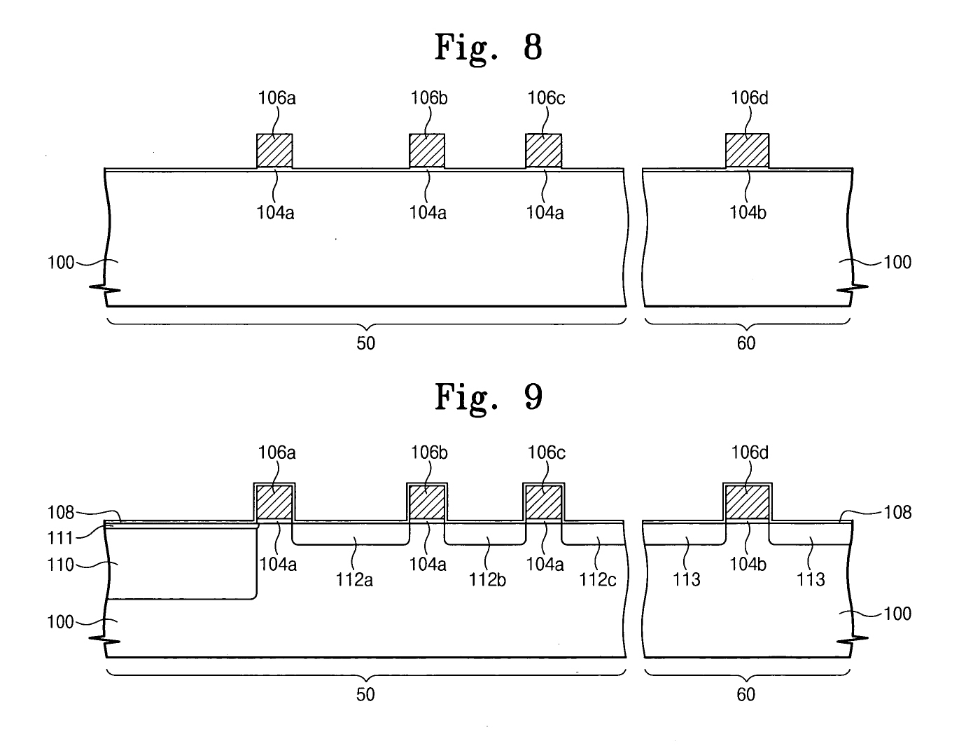

FIGS. 8 through 16 are sectional views taken along the lines I-I′ and II-II′ of FIG. 5 to illustrate a process of fabricating an image sensor according to another example embodiment of the present invention.

In the example embodiment of FIG. 8, a device isolation layer (not illustrated) may be formed in a substrate 100 having a pixel region 50 and a peripheral circuit region 60, to define first and second pixel active regions of the pixel region 50 and a peripheral active region of the peripheral circuit region 60. The second pixel active region may be connected to a given side of the first pixel active region.

In the example embodiment of FIG. 8, a pixel gate insulating layer 104a may be formed on the first and second pixel active regions. A peripheral gate insulating layer 104b may be formed on the peripheral active region. In an example, the pixel gate insulating layer 104a and the peripheral gate insulating layer 104b may be formed of the same material and/or to the same thickness. In this example, the pixel gate insulating layer 104a and the peripheral gate insulating layer 104b may be formed concurrently (e.g., simultaneously). Alternatively, in another example, the pixel gate insulating layer 104a and the peripheral gate insulating layer 104b may be formed of different materials and/or to different thicknesses. In this alternative example, the pixel gate insulating layer 104a and the peripheral gate insulating layer 104b may be formed sequentially (e.g., non-concurrently). Accordingly, it will be appreciated that the sequence of the processes of forming the pixel gate insulating layer 104a and the peripheral gate insulating layer 104b may be optional.

In the example embodiment of FIG. 8, a gate conductive layer may be formed on a top surface (e.g., an entirety of the top surface) of the substrate 100. Using the pixel gate insulating layers 104a and 104b as etch-stop layers, the gate conductive layer may be patterned to form a transfer gate 106a, a reset gate 106b, a sensing gate 106c, and a peripheral gate 106d. The gates 106a, 106b, 106c and 106d may be formed of a conductive material, for example, a doped polysilicon. After the forming of the gates 106a, 106b, 106c and 106d, the pixel gate insulating layer 104a and the peripheral gate insulating layer 104b may remain at first and second sides of the gates 106a, 106b, 106c and 106d.

In the example embodiment of FIG. 9, the remaining pixel/peripheral gate insulating layers 104a and 104b may be reduced (e.g., removed) to expose the peripheral active region and the first and second pixel active regions at both sides of the gates 106a, 106b, 106c and 106d. In an example, the remaining pixel/peripheral gate insulating layers 104a and 104b may be reduced (e.g., removed) by wet etching. Accordingly, plasma etch damages of the surfaces of the active regions at first and second sides of the gates 106a, 106b, 106c and 106d may be reduced.

In the example embodiment of FIG. 9, a buffer insulating layer 108 may be formed on the top surface (e.g., an entirety of the top surface) of the substrate 100. The buffer insulating layer 108 may be formed by performing a thermal oxidation process on the substrate 100. Accordingly, the buffer insulating layer 108 may be formed on the surfaces of the exposed active regions and on the side and top surfaces of the gates 106a, 106b, 106c and 106d.

In the example embodiment of FIG. 9, first dopant ions may be selectively implanted into the substrate 100 to form a photodiode region 110 in the first pixel active region. Second dopant ions may be selectively implanted into the substrate 100 to form a pinned doped region 111 at a surface of the first pixel active region. Third dopant ions may be selectively implanted into the substrate 100 to form a floating lower-concentration region 112a, a first lower-concentration region 112b, and a second lower-concentration region 112c. Fourth dopant ions may be selectively implanted into the substrate 100 to form a peripheral low-concentration region 113. In an example, if the peripheral lower-concentration region 113 and the floating lower-concentration region 112a are to be doped with the same-type dopants to the same concentration, the processes of the implanting the third and fourth dopant ions may be performed concurrently (e.g., simultaneously). Accordingly, as will be appreciated, the sequence of the processes of implanting the first through fourth dopant ions may be optional.

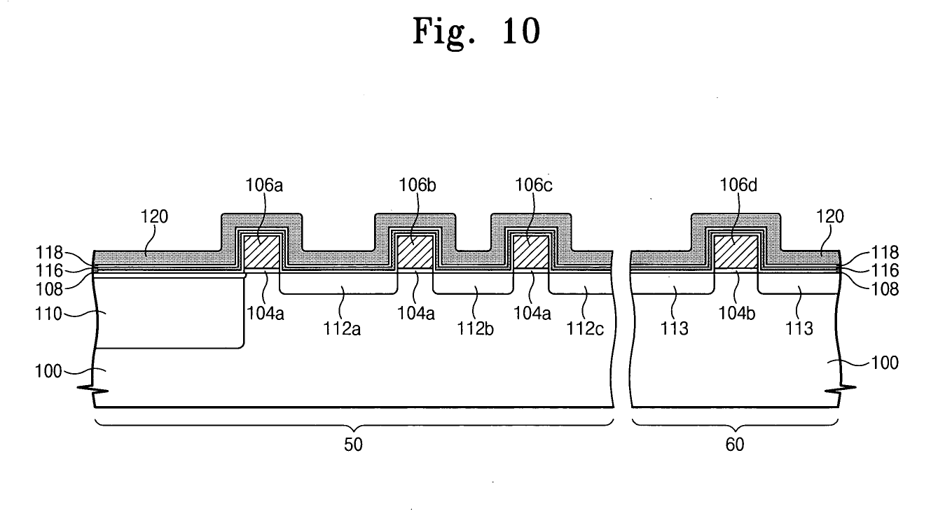

In the example embodiment of FIG. 10, a barrier insulating layer 116 may be conformally formed on the top surface (e.g., an entirety of the top surface) of the substrate 100. In an example, the barrier insulating layer 116 may be formed of the same material as that illustrated with reference to the example embodiment of FIG. 6. A first spacer insulating layer 118 may be conformally formed on the barrier insulating layer 116. In an example, the first spacer insulating layer 118 may be formed of an insulating material having an etch selectivity with respect to the barrier insulating layer 116. For example, the barrier insulating layer 116 may be formed of a nitride layer and the first spacer insulating layer 118 may be formed of an oxide layer. A second spacer insulating layer 120 may be formed on the first spacer insulating layer 118. In an example, the second spacer insulating layer 120 may be formed of an insulating material having an etch selectivity with respect to the first spacer insulating layer 118. For example, the second spacer insulating layer 120 may be formed of a nitride layer or a nitride oxide layer. The second spacer insulating layer 120 may be formed thicker than the first spacer insulating layer 118.

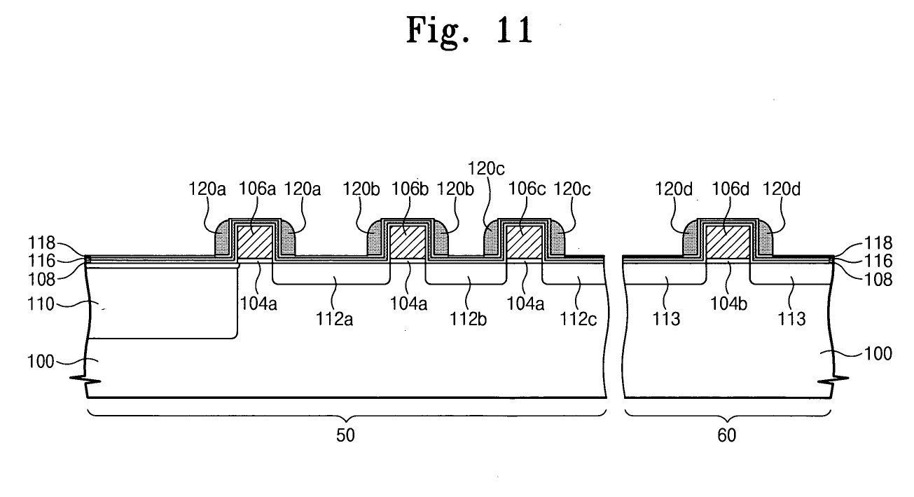

In the example embodiment of FIG. 11, a blanket anisotropic etch process may be performed on the second spacer insulating layer 120 using the first spacer insulating layer 118 as an etch-stop layer. Accordingly, an upper transfer pattern 120a may be formed on first and second sidewalls of the transfer gate 106a and an upper reset pattern 120b may be formed on first and second sidewalls of the reset gate 106b, an upper sensing pattern 120c may be formed on first and second sidewalls of the sensing gate 106c, and an upper peripheral pattern 120d may be formed on first and second sidewalls of the peripheral gate 106d. The first spacer insulating layer 118 on the active regions at the sides of the upper patterns 120a, 120b, 120c and 120d and also the first spacer insulating layer 118 on the top surfaces of the gates 106a, 106b, 106c and 106d may at least partially remain after the blanket anisotropic etch process.

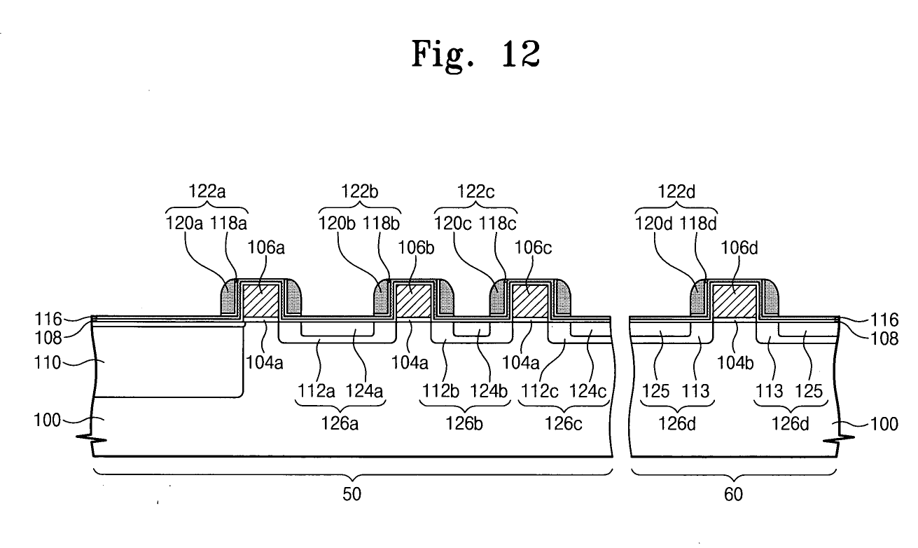

In the example embodiment of FIG. 12, the remaining first spacer insulating layer 118 may be etched using the barrier insulating layer 116 as an etch-stop layer. The remaining first spacer insulating layer 118 may be etched by wet etching. Accordingly, plasma etch damage of the barrier insulating layer 116 that is formed on the photodiode region 110 and the floating low-concentration region 112a may be reduced. The remaining first spacer insulating layer 118 may be wet-etched to form an upper transfer pattern 118a, an upper reset pattern 118b, an upper sensing pattern 118c, and an upper peripheral pattern 118d. The lower and upper transfer patterns 118a and 120a may collectively constitute a transfer spacer 122a, the lower and upper reset patterns 118b and 120b may collectively constitute a reset spacer 122b, the lower and upper sensing patterns 118c and 120c may collectively constitute a sensing spacer 122c, and the lower and upper peripheral patterns 118d and 120d may collectively constitute a peripheral spacer 122d. The remaining first spacer insulating layer 118 may be wet-etched to expose the barrier insulating layer 116 on the active regions at the sides of the spacers 122a, 122b, 122c and 122d and also the barrier insulating layer 116 on the top surfaces of the gates 106a, 106b, 106c and 106d.

In the example embodiment of FIG. 12, fifth dopant ions may be selectively implanted into the substrate 100 to form a floating higher-concentration region 124a, a first higher-concentration region 124b, and a second higher-concentration region 124c. Sixth dopant ions may be selectively implanted into the substrate 100 to form a peripheral higher-concentration region 125. Accordingly, a floating doped region 126a, first and second dopant-doped regions 126b and 126c, and a peripheral dopant-doped region 126d (e.g., see FIG. 6) may be formed. A given ion implantation mask pattern may be further provided if the fifth and sixth dopant ions are implanted. For example, at least one of the spacers 122a, 122b, 122c and 122d may also be used as an ion implantation mask. The sequence of the processes of implanting the fifth and sixth dopant ions may be optional (e.g., fifth follows sixth, sixth follows fifth, fifth concurrent with sixth, etc.). In an example, if the higher-concentration regions 124a, 124b, 124c and 1245 are to be doped with the same-type dopants and/or to the same concentration, the processes of the implanting the firth and sixth dopant ions may be performed concurrently (e.g., simultaneously).

In the example embodiment of FIG. 12, the process of implanting the fifth dopant ions may be omitted. In this case, the floating doped region 126a may include only the floating lower-concentration region 112a, the first dopant-doped region 126b may include only the first lower-concentration region 112b, and the second dopant-doped region 126b may include only second lower-concentration region 112c.

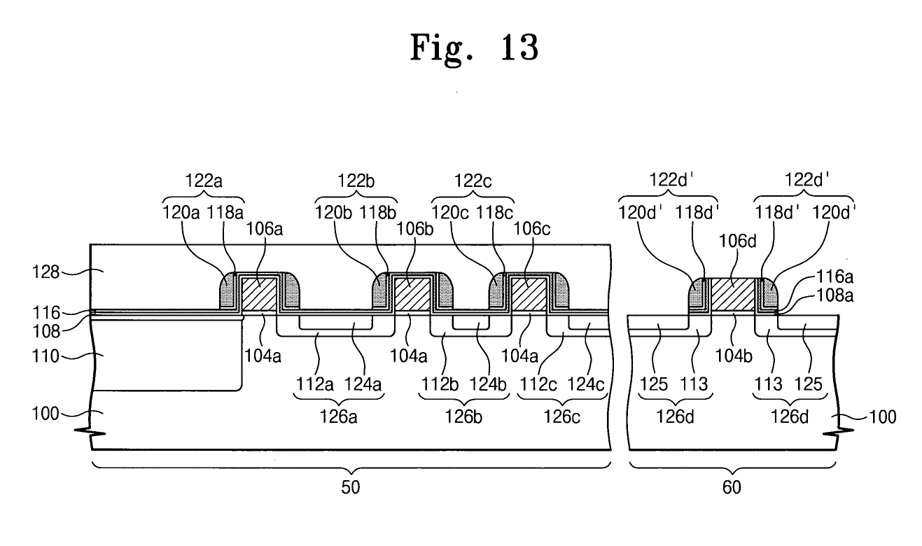

In the example embodiment of FIG. 13, a mask pattern 128 may be formed on the substrate 100. The mask pattern 128 may continuously cover the photodiode region 110, the transfer gate 106a, the floating doped region 126a, the reset gate 106b, the first dopant-doped region 126b, the sensing gate 106c, and the second dopant-doped region 126c. The peripheral circuit region 60 may be exposed. For example, the mask pattern 128 may not be formed in the peripheral circuit region 60. In another example, the mask pattern 128 may cover an entirety of the pixel region 50.

In the example embodiment of FIG. 13, using the mask pattern 128 as an etch mask, the exposed barrier/buffer insulating layers 116 and 108 of the peripheral circuit region 60 may be sequentially etched to expose a top surface of the peripheral gate 106d and the peripheral dopant-doped region 126d. The barrier insulating layer 116 of the peripheral circuit region 60 may be etched by anisotropic etching and the buffer insulating layer 108 may be etched by wet etching. Accordingly, a peripheral barrier pattern 116a and a peripheral buffer pattern 108a (e.g., see FIG. 6) may be formed.

In the example embodiment of FIG. 13, if the barrier insulating layer 116 and the buffer insulating layer 108 are etched using the mask pattern 128 as an etch mask, a portion of the peripheral spacer 122d may also be etched. For example, a portion of the upper peripheral pattern 120d may be etched if the barrier insulating layer 116 is etched anisotropically, and the lower peripheral pattern 118d may be etched if the buffer insulating layer 108 is wet-etched. Accordingly, the top of an etched peripheral spacer 122d′ may be lower in height than the top of the transfer spacer 122a. Reference numerals 118d′ and 120d′ may denote an etched lower peripheral pattern and an etched upper peripheral pattern, respectively. An exposed portion of the peripheral dopant-doped region 126d may be located beside the peripheral spacer 122d′.

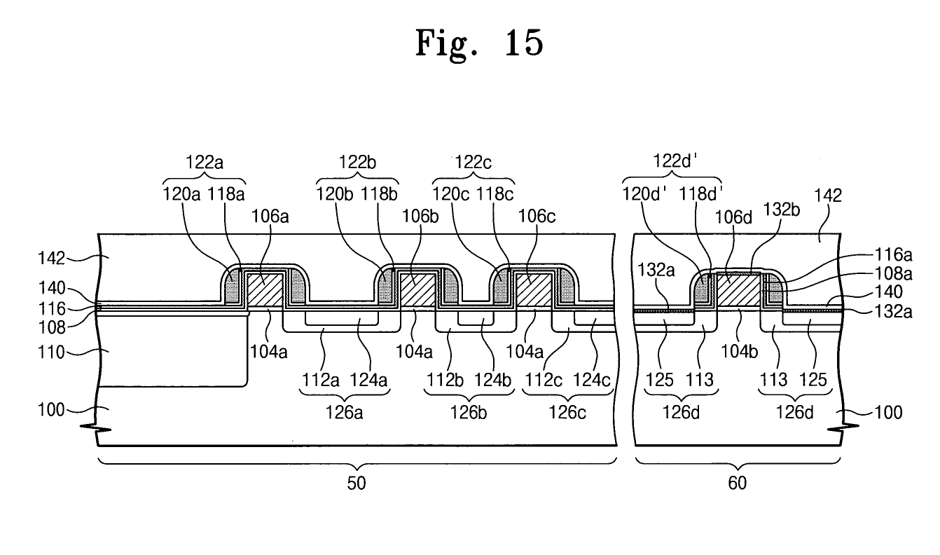

In the example embodiment of FIG. 15, the mask pattern 128 may be reduced (e.g., removed) from the substrate 100. Thereafter, a metal layer 130 may be formed on the entire top surface of the substrate 100, and a silicification process may be performed on the substrate 100. Accordingly, a first peripheral metal silicide 132a may be formed on the exposed surface of the peripheral dopant-doped region 126a, and a second peripheral metal silicide 132b may be formed on the exposed top surface of the peripheral gate 106d. The barrier insulating layer 116 may reduce (e.g., prevent) silicification of the transfer gate 106a, the reset gate 106b, the sensing gate 106c, the photodiode region 110, the floating doped region 126a, the first dopant-doped region 126b, and/or the second dopant-doped region 126c. For example, the barrier insulating layer 116 may reduce (e.g., minimize) the infiltration of the metal elements of the metal layer 130 into the photodiode region 110 and the floating doped region 126a.

In the example embodiment of FIG. 15, a non-reacted metal layer 130 may be reduced (e.g., removed) from the substrate 100. Thereafter, a first dielectric layer 140 may be conformally formed on the top surface (e.g., an entirety of the top surface) of the substrate 100, and a second dielectric layer 142 may be formed on the first dielectric layer 140. The first dielectric layer 140 may have an etch selectivity with respect to the second dielectric layer 142. For example, the second dielectric layer 142 may be formed of an oxide layer and the first dielectric layer 140 may be formed of a nitride layer and/or a nitride oxide layer.

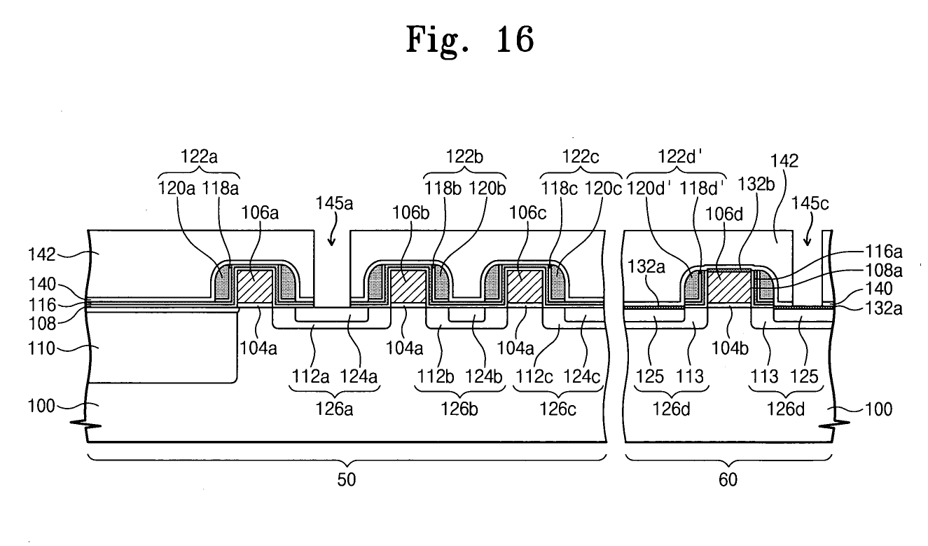

In the example embodiment of FIG. 16, a first contact hole 146a may be formed to sequentially penetrate the second dielectric layer 142 and the first dielectric layer 140 and thus expose the floating doped region 126a. A second contact hole (e.g., see 145b of FIG. 5) may be formed to sequentially penetrate the second dielectric layer 142, the first dielectric layer 140, the barrier insulating layer 116 and the buffer insulating layer 108 and thus expose the sensing gate 106c. A third contact hole 145c may be formed to penetrate the second dielectric layer 142 and the first dielectric layer 140 and thus expose the first peripheral metal silicide 132a. In an example, the first contact hole 146a and the third contact hole 146c may be formed concurrently (e.g., simultaneously). In another example, the first contact hole 146a, the second contact hole (e.g., see 145b of FIG. 5), and the third contact hole 146c may be formed concurrently (e.g., simultaneously). Furthermore, in another example, the first, second and third contact holes 146a, 146b and 146c may be formed sequentially (e.g., non-concurrently).

In the example embodiment of FIG. 16, a first contact plug 147a, a second contact plug (not illustrated), a third contact plug 147c, a local interconnection 150a, and a peripheral interconnection 150b may be formed to manufacture the image sensor illustrated in the example embodiment of FIG. 6.

In the example embodiment of FIGS. 8 through 16, the barrier insulating layer 116 covering the photodiode region 110 and the floating doped region 126a may be formed and the first and second spacer insulating layers 118 and 120 may be sequentially formed on the barrier insulating layer 116. Thereafter, the second spacer insulating layer 120 and the first spacer insulating layer 118 may be etched to form the spacers 122a, 122b, 122c and 122d. The first spacer insulating layer 118 may be etched by wet etching. Consequently, the photodiode region 110 and the floating doped region 126a may be at least partially protected from etch damage. Accordingly, dark current may be reduced (e.g., minimized) and the characteristics of the image sensor may thereby be improved.

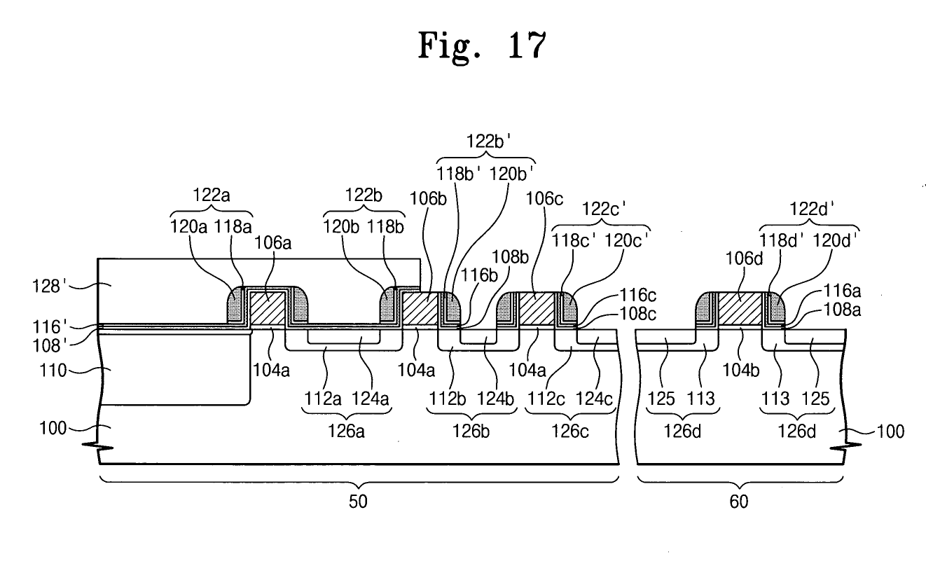

In another example embodiment of the present invention, a process of forming the image sensor illustrated in the example embodiment of FIG. 7 may be similar to the above-described image sensor forming process described with respect to FIGS. 8 through 16. For example, the process of forming the image sensor of FIG. 7 may first perform the steps described above with respect to FIGS. 8 through 12. FIG. 17, described below, follows FIG. 12, sequentially, in the formation process of the image sensor of FIG. 7.

FIG. 17 is a sectional view taken along the lines I-I′ and II-II′ of FIG. 5 to illustrate a process of fabricating an image sensor illustrated in FIG. 7 according to another example embodiment of the present invention.

In the example embodiment of FIGS. 7 and 17, a mask pattern 128′ may be formed on a substrate 100 having spacers 122a, 122b, 122c and 122d and doped regions 126a, 126b, 126c and 126d. The mask pattern 128′ may cover (e.g., continuously cover) the photodiode region 110, the transfer gate 106a, the floating doped region 126a, and a portion of a top surface of the reset gate 106b. The mask pattern 128′ may cover a first reset spacer 122b adjacent to a floating doped region 126a, and may not cover a second reset spacer 122b′ adjacent to a first dopant-doped region 126b. The peripheral circuit region 60, another portion of the top surface of the reset gate 106b, the sensing gate 106c, the first dopant-doped region 126b, and the second dopant-doped region 126c may be exposed after the forming of the mask pattern 128′.

In the example embodiment of FIGS. 7 and 17, the barrier insulating layer 116 and the buffer insulating layer 108 of the pixel region 50 and the peripheral circuit region 60 may be sequentially etched using the mask pattern 138′ as an etch mask. Accordingly, another portion of the top surface of the reset gate 106b, the top surfaces of the sensing/peripheral gates 106c and 106d, and the first, second and peripheral dopant-doped regions 126b, 126c and 126d may be exposed. In addition, the reset barrier pattern 116b, the reset buffer pattern 108b, the sensing barrier pattern 116c, and the sensing buffer pattern 108c (e.g., illustrated in FIG. 7) may be formed.

In the example embodiment of FIGS. 7 and 17, during the etching process using the mask pattern 128′ as an etch mask, the barrier insulating layer 116 may be etched by anisotropic etching and the buffer insulating layer 108 may be etched by wet etching.

In the example embodiment of FIGS. 7 and 17, during the etching process using the mask pattern 128′ as an etch mask, a portion of the second reset spacer 122b and a portion of the sensing spacer 122c may be etched together with a portion of the peripheral spacer 122d. The etched second reset spacer 122b′ may include an etched lower reset pattern 118b′ and an etched upper reset pattern 120b′. The etched sensing spacer 122c′ may include an etched lower sensing pattern 118c′ and an etched upper sensing pattern 120c′. Accordingly, the tops of the second reset spacer 122b′ and the sensing spacer 122c′ may be formed lower than the first reset spacer 122a protected by the mask pattern 128′.

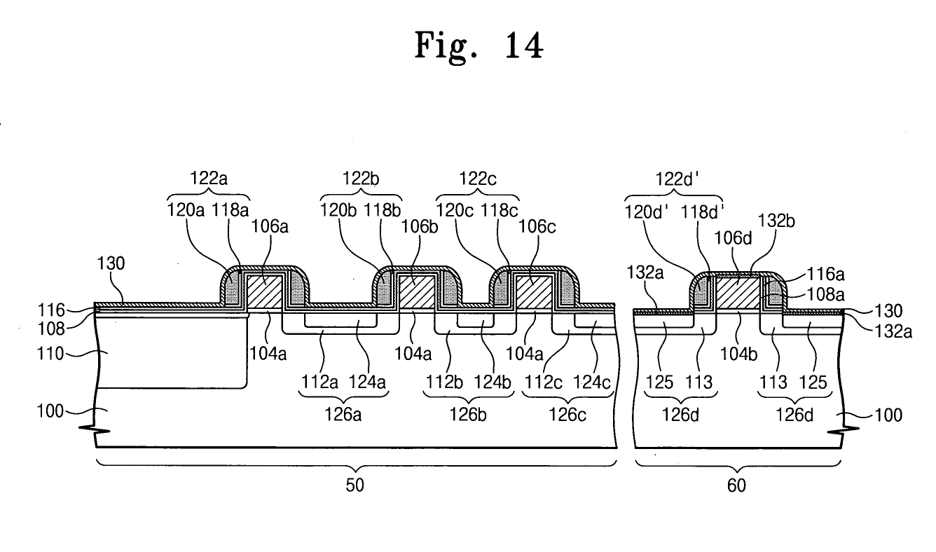

In the example embodiment of FIGS. 7 and 17, after reducing (e.g., removing) the mask pattern 128′, a metal layer forming process, a silicification process and the subsequent processes may be performed in the same manner as described above with reference to FIGS. 14 and 16. Accordingly, the image sensor illustrated in FIG. 7 may be manufactured.

In another example embodiment of the present invention, the barrier insulating layer covering the photodiode region and the floating doped region may be formed, and the first spacer insulating layer having an etch selectivity with respect to the barrier insulating layer and the second spacer insulating layer having an etch selectivity with respect to the first spacer insulating layer may be formed sequentially. The first spacer insulating layer and the first spacer insulating layer may be etched to form the spacers. Because the barrier insulating layer may at least partially protect the photodiode region and the floating doped region, a dark current may be reduced (e.g., minimized) and characteristics of the resultant image sensor may thereby be improved. In addition, because the first spacer insulating layer may be etched by wet etching, defects that may be generated in the photodiode region and the floating doped region may likewise be reduced.

Example embodiments of the present invention being thus described, it will be obvious that the same may be varied in many ways. For example, while above-described example embodiments of the present invention are generally directed to CMOS image sensors, it is understood that other example embodiments of the present invention may be directed to any type of well-known image sensor.

Further, while certain layers and/or elements are described as “formed of” certain materials, it is understood that “formed of” is intended to be interpreted inclusively, and not exclusively. For example, an element “formed of” a given material may include the given material and any other additional materials.

Such variations are not to be regarded as a departure from the spirit and scope of example embodiments of the present invention, and all such modifications as would be obvious to one skilled in the art are intended to be included within the scope of the following claims.

What is claimed is:

1. An image sensor, comprising:
a photodiode region disposed in a first pixel active region defined in a substrate;
a floating doped region disposed in a second pixel active region defined in the substrate and connected to a given side of the first pixel active region;
a pixel gate insulating layer and a transfer gate stacked on the second pixel active region between the photodiode region and the floating doped region;
a barrier insulating layer covering the photodiode region, the transfer gate and the floating doped region;
a buffer insulating layer interposed between the barrier insulating layer and the photodiode region and between the barrier insulating layer and the floating doped region; and
a transfer spacer disposed on at least one sidewall of the transfer gate with the barrier insulating layer interposed therebetween, the transfer spacer including an L-shaped lower transfer pattern and an upper transfer pattern disposed on the lower transfer pattern, the lower transfer pattern including an insulating material having an etch selectivity with respect to the barrier insulating layer, the upper transfer pattern including an insulating material having an etch selectivity with respect to the lower transfer pattern.

2. The image sensor of claim 1, wherein the transfer spacer is disposed on first and second sidewalls of the transfer gate.

3. The image sensor of claim 1, wherein the substrate includes a pixel region and a peripheral circuit region, the first pixel active region and the second pixel active region are defined in the pixel region.

4. The image sensor of claim 3, further comprising:
a peripheral gate insulating layer and a peripheral gate stacked on a peripheral active region defined in the peripheral circuit region;
a peripheral dopant-doped region disposed in a peripheral active region at first and second sides of the peripheral gate;
a peripheral spacer disposed on first and second sidewalls of the peripheral gate, the peripheral spacer including an L-shaped lower peripheral pattern and an upper peripheral pattern disposed on the lower peripheral pattern;
a peripheral barrier pattern interposed between the lower peripheral pattern and the peripheral gate and between the lower peripheral pattern and the peripheral active region;
a peripheral buffer pattern interposed between the peripheral barrier pattern and the peripheral gate and between the peripheral barrier pattern and the peripheral active region; and
a first peripheral metal silicide disposed on the peripheral dopant-doped region at one side of the peripheral spacer.

5. The image sensor of claim 4, wherein the peripheral barrier pattern includes the same material as the barrier insulating layer, and the peripheral buffer pattern includes the same material as the buffer insulating layer.

6. The image sensor of claim 4, further comprising:
a second peripheral metal silicide disposed on a top surface of the peripheral gate, wherein the first peripheral metal silicide and the second peripheral metal silicide include the same metal.

7. The image sensor of claim 4, wherein the top of the peripheral spacer is lower in height than the top of the transfer spacer.

8. The image sensor of claim 1, wherein the buffer insulating layer is further interposed between the transfer gate and the barrier insulating layer.

9. The image sensor of claim 1, further comprising:
a reset gate and a sensing gate disposed laterally spaced apart from each other on the second pixel active region at a given side of the transfer gate; and
a first dopant-doped region and a second dopant-doped region disposed in the second pixel active region at first and second sides of the sensing gate, respectively, wherein the floating doped region is disposed between the transfer gate and the reset gate, the first dopant-doped region is disposed between the reset gate and the sensing gate, and the pixel gate insulating layer is further interposed between the reset gate and the second pixel active region and between the sensing gate and the second pixel active region.

10. The image sensor of claim 9, wherein the barrier insulating layer laterally extends to cover the reset gate, the first dopant-doped region, the sensing gate, and the second dopant-doped region, and the buffer insulating layer is interposed between the barrier insulating layer and the first dopant-doped region and between the barrier insulating layer and the second dopant-doped region.

11. The image sensor of claim 10, further comprising:
a reset spacer disposed on first and second sidewalls of the reset gate with the barrier insulating layer interposed therebetween, the reset spacer including an L-shaped lower reset pattern and an upper reset pattern disposed on the lower reset pattern; and
a sensing spacer disposed on both sidewalls of the sensing gate with the barrier insulating layer interposed therebetween, the sensing spacer including an L-shaped lower sensing pattern and an upper sensing pattern disposed on the lower sensing pattern,
wherein the lower reset pattern and the lower sensing pattern include the same material as the lower transfer pattern, and the upper reset pattern and the upper sensing pattern include the same material as the upper transfer pattern.

12. The image sensor of claim 10, wherein the buffer insulating layer is interposed between the barrier insulating layer and the reset gate and also between the barrier insulating layer and the sensing gate.

13. The image sensor of claim 9, wherein the barrier insulating layer laterally extends to cover a first sidewall of the reset gate adjacent to the floating doped region and a portion of the top surface of the reset gate.

14. The image sensor of claim 13, further comprising:
a first reset spacer disposed on the first sidewall of the reset gate with the barrier insulating layer interposed therebetween, the first reset spacer including a first L-shaped lower reset pattern and a first upper reset pattern disposed on the first lower reset pattern;
a second reset spacer disposed on a second sidewall of the reset gate adjacent to the first dopant-doped region, the second reset spacer including a second L-shaped lower reset pattern and a second upper reset pattern disposed on the second lower reset pattern;
a sensing spacer disposed on first and second sidewalls of the sensing gate, the sensing spacer including an L-shaped lower sensing pattern and an upper sensing pattern disposed on the lower sensing pattern; and
a first pixel metal silicide disposed on the surface of the first dopant-doped region between the second reset spacer and the sensing spacer and on the surface of the second dopant-doped region at a given side of the sensing spacer,
wherein the first lower reset pattern, the second lower reset pattern, and the lower sensing pattern include the same material as the lower transfer pattern, and the first upper reset pattern, the second upper reset pattern, and the upper sensing pattern include same material as the upper transfer pattern.

15. The image sensor of claim 14, further comprising:
a reset barrier pattern interposed between the second reset spacer and the reset gate and between the second reset spacer and the second pixel active region;
a reset buffer pattern interposed between the reset barrier pattern and the reset gate and between the reset barrier pattern and the second pixel active region;
a sensing barrier pattern interposed between the sensing spacer and the sensing gate and between the sensing spacer and the second pixel active region; and
a sensing buffer pattern interposed between the sensing barrier pattern and the sensing gate and between the sensing barrier pattern and the second pixel active region,
wherein the reset barrier pattern and the sensing barrier pattern include the same material as the barrier insulating layer, and the reset buffer pattern and the sensing buffer pattern include the same material as the barrier insulating layer.

16. The image sensor of claim 14, further comprising:
a second pixel metal silicide disposed on a portion of the top surface of the reset gate and the top surface of the sensing gate, wherein the first pixel metal silicide and the second pixel metal silicide include the same metal.

17. The image sensor of claim 14, wherein the top of the second reset spacer and the top of the sensing spacer are lower in height than the top of the first reset spacer.

18. A method for fabricating an image sensor, comprising:
defining a first pixel active region and a second pixel active region in a substrate;
stacking a pixel gate insulating layer and a transfer gate on the second pixel active region adjacent to the first pixel active region;
forming a buffer insulating layer on the substrate;
forming a photodiode region in the first pixel active region;
forming a floating doped region in the second pixel active region adjacent to a given side of the transfer gate;
forming, on a top surface of the substrate, a barrier insulating layer, a first spacer insulating layer having an etch selectivity with respect to the barrier insulating layer, and a second spacer insulating layer having an etch selectivity with respect to the first spacer insulating layer; and
etching the second spacer insulating layer and the first spacer insulating layer to form a transfer spacer on first and second sidewalls of the transfer gate.

19. The method of claim 18, wherein the barrier insulating layer, the first spacer insulating layer and the second spacer insulating layer are sequentially formed by first forming the barrier insulating layer, second forming the first spacer insulating layer and third forming the second spacer insulating layer.

20. The method of claim 18, wherein the barrier insulating layer, the first spacer insulating layer and the second spacer insulating layer cover the entire top surface of the substrate.

21. The method of claim 18, wherein the second spacer insulating layer is blanket-anisotropic-etched using the first spacer insulating layer as an etch-stop layer, and the first spacer insulating layer is wet-etched using the barrier insulating layer as an etch-stop layer.

22. The method of claim 18, wherein the substrate includes a pixel region and a peripheral circuit region, the first pixel active region and the second pixel active region are defined in the pixel region.

23. The method of claim 22, further comprising before forming the barrier insulating layer:
stacking a peripheral gate insulating layer and a peripheral gate on a peripheral active region defined in the peripheral circuit region; and
forming a peripheral dopant-doped region in the peripheral active region at first and second sides of the peripheral gate,
wherein a peripheral spacer is formed on first and second sidewalls of the peripheral gate during the forming of the transfer spacer.

24. The method of claim 23, further comprising:
forming a mask pattern that covers the photodiode region, the transfer gate and the floating doped region;
etching the barrier insulating layer and the buffer insulating layer using the mask pattern as an etch mask, to expose the peripheral dopant-doped region at a given side of the peripheral spacer and the top surface of the peripheral gate;
reducing the mask pattern;
forming a metal layer on the top surface of the substrate;
performing a silicification process on the substrate; and
reducing a non-reacted metal.

25. The method of claim 24, wherein the barrier insulating layer is anisotropically etched and the buffer insulating layer is wet-etched, using the mask pattern as an etch mask.

26. The method of claim 24, wherein a portion of the peripheral spacer is etched during the etching of the barrier insulating layer and the buffer insulating layer using the mask pattern as an etch mask.

27. The method of claim 18, further comprising before the forming of the barrier insulating layer:
forming a reset gate and a sensing gate that are disposed laterally spaced apart from each other on the second pixel active region at a given side of the transfer gate; and
forming a first dopant-doped region and a second dopant-doped region respectively in the second pixel active region at first and second sides of the sensing gate,
wherein the floating doped region is formed between the transfer gate and the reset gate and the first dopant-doped region is formed between the reset gate and the sensing gate,
the pixel gate insulating layer is formed between the reset gate and the second pixel active region and between the sensing gate and the second pixel active region, and
a reset spacer is formed on first and second sidewalls of the reset gate and a sensing spacer is formed on first and second sidewalls of the sensing gate during the forming of the transfer spacer.

28. The method of claim 27, further comprising:
forming a mask pattern that covers the photodiode region, the transfer gate, the floating doped region and a portion of the top surface of the reset gate;
etching the barrier insulating layer and the buffer insulating layer using the mask pattern as an etch mask, to expose another portion of the top surface of the reset gate, the first dopant-doped region between the reset spacer and the sensing spacer, and the second dopant-doped region at a given side of the sensing spacer;
reducing the mask pattern;
forming a metal layer on the entire top surface of the substrate;
performing a silicification process on the substrate; and
reducing a non-reacted metal.

29. The method of claim 28, wherein the barrier insulating layer is anisotropically etched, and the buffer insulating layer is wet-etched using the mask pattern as an etch mask.

30. The method of claim 28, wherein a portion of the reset spacer adjacent to the first dopant-doped region and a portion of the sensing spacer are etched during the etching of the barrier insulating layer and the buffer insulating layer using the mask pattern as an etch mask.

31. A method for fabricating an image sensor, comprising:
forming at least one gate on a substrate;
forming first, second and third layers on the at least one gate;
first etching the third layer with a first etching process, the second layer configured to be resistant to the first etching process, the first etching process reducing at least a portion of the third layer and exposing at least a portion of the second layer; and
second etching at least the exposed portion of the second layer with a second etching process other than the first etching process, the first layer configured to be resistant to the second etching process.

32. The method of claim 31, wherein the first layer is a barrier insulating layer, the second layer is a first spacer insulating layer and the third layer is a second spacer insulating layer.

33. The method of claim 31, wherein the first etching process is a blanket-anisotropic-etching process and the second etching process is a wet-etching process.

34. The method of claim 31, wherein the at least one gate includes one or more of a transfer gate, a reset gate, a sensing gate and a peripheral gate.
